(19) United States
(12) Patent Application Publication
(10) Pub. No.: US 2012/0273794 A1
(43) Pub. Date: Nov. 1, 2012

(54) SEMICONDUCTOR LIGHT EMITTING DEVICE, WAFER, AND METHOD FOR MANUFACTURING SEMICONDUCTOR LIGHT EMITTING DEVICE

(75) Inventors: Shinji SAITO, Kanagawa-ken (JP); Shinya Nunoue, Chiba-ken (JP); Rei Hashimoto, Tokyo (JP)

(73) Assignee: Kabushiki Kaisha Toshiba, Tokyo (JP)

(21) Appl. No.: 13/407,191

(22) Filed: Feb. 28, 2012

(30) Foreign Application Priority Data
Apr. 28, 2011 (JP) 2011-102367

(51) Int. Cl. H01L 33/32; H01L 33/00; H01L 29/06; H01L 33/20

(52) U.S. Cl. 257/76; 257/94; 438/22; 257/622; 257/E29.026; 257/E33.025; 257/E33.027; 257/E33.006

(57) ABSTRACT

According to one embodiment, a semiconductor light emitting device includes a first semiconductor layer, an active layer, and a second semiconductor layer. The first layer has a first upper surface and a first side surface. The active layer has a first portion covering the first upper surface and having a second upper surface, and a second portion covering the first side surface and having a second side surface. The second layer has a third portion covering the second upper surface, and a fourth portion covering the second side surface. The first and second layers include a nitride semiconductor. The first portion along a stacking direction has a thickness thicker than the second portion along a direction from the first side surface toward the second side surface. The third portion along the stacking direction has a thickness thicker than the fourth portion along the direction.

### CROSS-REFERENCE TO RELATED APPLICATIONS

This application is based upon and claims the benefit of priority from the prior Japanese Patent Application No. 2011-102367, filed on Apr. 28, 2011; the entire contents of which are incorporated herein by reference.

### FIELD

Embodiments described herein relate generally to a semiconductor light emitting device, a wafer, and a method for manufacturing the light emitting device.

### BACKGROUND

Semiconductor light emitting devices such as LDs (Laser Diodes), LEDs (Light Emitting Diodes), and the like are widely used in display apparatuses, illumination apparatuses, recording apparatuses, and the like. Higher performance and lower prices are necessary for semiconductor light emitting devices.

In the case where, for example, a semiconductor light emitting device is constructed using a sapphire substrate, many defects occur due to lattice mismatch; and there is a limit to high performance. On the other hand, although there are few defects when constructing a semiconductor light emitting device using a GaN substrate, the semiconductor light emitting device is expensive because the GaN substrate is expensive.

### BRIEF DESCRIPTION OF THE DRAWINGS

FIG. 1 is a schematic cross-sectional view illustrating a semiconductor light emitting device according to a first embodiment;

FIG. 2 is a schematic cross-sectional view illustrating a portion of the semiconductor light emitting device according to the first embodiment;

FIG. 3 is a schematic cross-sectional view illustrating the semiconductor light emitting device according to the first embodiment;

FIG. 4 is a flowchart illustrating a method for manufacturing the semiconductor light emitting device according to the first embodiment;

FIG. 5A and FIG. 5B are schematic views illustrating the method for manufacturing the semiconductor light emitting device according to the first embodiment;

FIG. 6A, FIG. 6B, FIG. 7A, FIG. 7B, and FIG. 8 are schematic cross-sectional views in order of the processes, illustrating the method for manufacturing the semiconductor light emitting device according to the first embodiment;

FIG. 9 is a schematic cross-sectional view illustrating a semiconductor light emitting device according to a second embodiment;

FIG. 10A and FIG. 10B are schematic views illustrating a method for manufacturing the semiconductor light emitting device according to the second embodiment;

FIG. 11A and FIG. 11B are schematic plan views illustrating another method for manufacturing the semiconductor light emitting device according to the second embodiment;

FIG. 12 is a schematic cross-sectional view illustrating a wafer according to a third embodiment; and

FIG. 13 is a schematic cross-sectional view illustrating a wafer according to a fourth embodiment.

### DETAILED DESCRIPTION

According to one embodiment, a semiconductor light emitting device includes a first semiconductor layer of a first conductivity type, an active layer, a second semiconductor layer of a second conductivity type. The first semiconductor layer includes a nitride semiconductor and has a first upper surface and a first side surface. The active layer has a first portion and a second portion. The first portion covers at least a portion of the first upper surface and has a second upper surface stacked with the first upper surface along a stacking direction. The second portion covers at least a portion of the first side surface and has a second side surface stacked with the first side surface along a first direction. The second semiconductor layer has a third portion and a fourth portion. The third portion covers at least a portion of the second upper surface. The fourth portion covers at least a portion of the second side surface. The second conductivity type is different from the first conductivity type. The second semiconductor layer includes a nitride semiconductor. A thickness of the first portion along the stacking direction is thicker than a thickness of the second portion along the first direction. A thickness of the third portion along the stacking direction is thicker than a thickness of the fourth portion along the first direction.

According to another embodiment, a wafer includes a substrate of a semiconductor, an oxide crystal film, an oxide layer, and a semiconductor crystal film. The substrate has a major surface. The oxide crystal film is provided on the major surface. The oxide layer is provided on a portion of the oxide crystal film. The oxide layer has a first pattern portion. The semiconductor crystal film is provided on a first region and a second region of the oxide crystal film. The first region and the second region are disposed on two sides of the first pattern portion. The semiconductor crystal film has a crystal orientation reflecting a crystal orientation of the substrate. The semiconductor crystal film includes a nitride semiconductor. The semiconductor crystal film has a gap provided on the first pattern portion between at least a portion of the semiconductor crystal film grown from the first region and at least a portion of the semiconductor crystal film grown from the second region.

According to another embodiment, a method is disclosed for manufacturing a semiconductor light emitting device. The method can include forming a first oxide crystal film on a major surface of a substrate of a semiconductor. The method can include forming a first oxide layer on a portion of the first oxide crystal film, the first oxide layer having a first pattern portion. In addition, the method can include growing a first semiconductor crystal film on a first region and a second region of the first oxide crystal film. The first region and the second region are disposed on two sides of the first pattern portion. The first semiconductor crystal film has a crystal orientation reflecting a crystal orientation of the substrate. The first semiconductor crystal film includes a nitride semiconductor. The growing of the first semiconductor crystal film includes making a gap on the first pattern portion between at least a portion of the first semiconductor crystal film grown from the first region and at least a portion of the first semiconductor crystal film grown from the second region.

Various embodiments will be described hereinafter with reference to the accompanying drawings.

The drawings are schematic or conceptual; and the relationships between the thicknesses and the widths of portions, the proportions of sizes among portions, and the like are not necessarily the same as the actual values thereof. Further, the dimensions and the proportions may be illustrated differently among the drawings, even for identical portions.

In the specification and the drawings of the application, components similar to those described in regard to a drawing thereinabove are marked with like reference numerals, and a detailed description is omitted as appropriate.

### First Embodiment

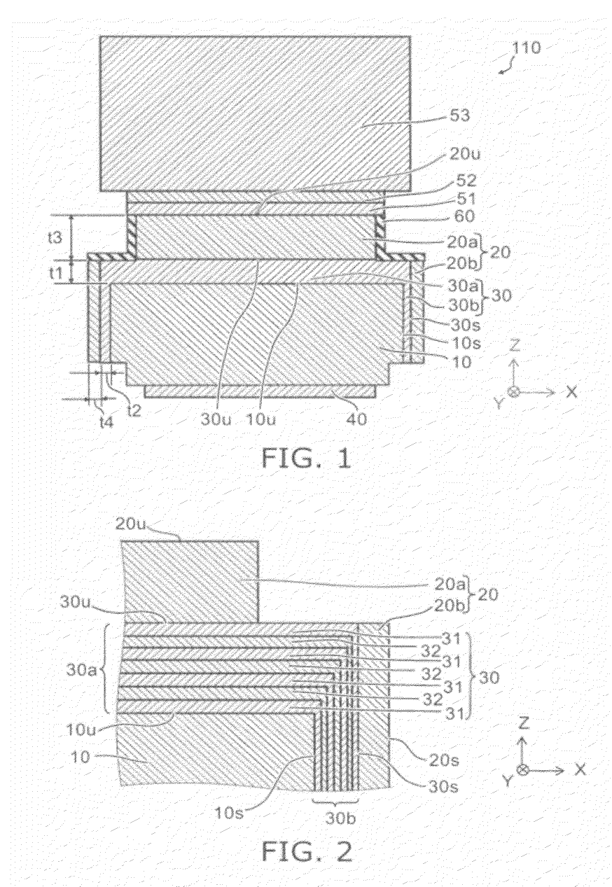

FIG. 1 is a schematic cross-sectional view illustrating the configuration of a semiconductor light emitting device according to a first embodiment. As illustrated in FIG. 1, the semiconductor light emitting device 110 according to the embodiment includes a first semiconductor layer 10, a second semiconductor layer 20, and an active layer 30. The active layer 30 has a portion between the first semiconductor layer 10 and the second semiconductor layer 20. The semiconductor light emitting device 110 of the specific example is a LD.

The first semiconductor layer 10 includes a nitride semiconductor. The first semiconductor layer 10 has a first conductivity type. The second semiconductor layer 20 includes a nitride semiconductor. The second semiconductor layer 20 has a second conductivity type. The second conductivity type is a conductivity type that is different from the first conductivity type. For example, the first conductivity type is an n type; and the second conductivity type is a p type. However, the first conductivity type may be the p type; and the second conductivity type may be the n type. Hereinbelow, an example is described in which the first conductivity type is the n type and the second conductivity type is the p type.

The active layer 30 has a first portion 30a covering at least a portion of an upper surface 10u of the first semiconductor layer 10 and a second portion 30b covering at least a portion of a side surface 10s of the first semiconductor layer 10.

The second semiconductor layer 20 has a third portion 20a covering at least a portion of an upper surface 30u of the first portion 30a and a fourth portion 20b covering at least a portion of a side surface 30s of the second portion 30b.

Thus, the first semiconductor layer 10 has a first upper surface (the upper surface 10u) and a first side surface (the side surface 10s)

The active layer 30 has the first portion 30a and the second portion 30b. The first portion 30a covers at least a portion of the first upper surface and has a second upper surface (the upper surface 30u). The second upper surface is stacked with the first upper surface along a stacking direction. The second portion 30b covers at least a portion of the first side surface and has a second side surface (the side surface 30s). The second side surface is stacked with the first side surface along a first direction.

The second semiconductor layer 20 has a third portion 20a and a fourth portion 20b. The third portion 20a covers at least a portion of the second upper surface and has a third upper surface (upper surface 20u). The fourth portion 20b covers at least a portion of the second side surface and has a third side surface (the side surface 20s).

Herein, the vertical direction is taken to be the stacking direction. In other words, the direction from the upper surface 10u of the first semiconductor layer 10 toward the upper surface 30u of the active layer 30 is taken to be the stacking direction. An axis parallel to the stacking direction is taken as a Z-axis. One axis perpendicular to the Z-axis is taken as an X-axis. An axis perpendicular to the Z-axis and the X-axis is taken as a Y-axis.

A direction from the side surface 10s of the first semiconductor layer 10 toward the side surface 30s of the second portion 30b is taken as an X-axis direction (the first direction).

For example, the side surface 10s of the first semiconductor layer 10 is a surface along the Z-axis and the Y-axis. For example, the first semiconductor layer 10 has two side surfaces 10s that are opposed to each other along the X-axis. In this example, two second portions 30b are provided.

The two second portions 30b cover at least portions of the two side surfaces 10s, respectively.

In this example, two fourth portions 20b are provided. The two fourth portions 20b cover at least portions of the two second portions 30b, respectively.

The two second portions 30b oppose each other along the X-axis direction. The two fourth portions 20b oppose each other along the X-axis direction.

As described below, the first portion 30a and the second portion 30b are formed by the active layer 30 being formed to cover the upper surface 10u and the side surface 10s of the first semiconductor layer 10. A thickness t2 of the second portion 30b is thinner than a thickness t1 of the first portion 30a due to the anisotropy when forming the active layer 30.

The second semiconductor layer 20 is formed by forming a film used to form the second semiconductor layer 20 to cover the upper surface 30u and the side surface 30s of the active layer 30. The second semiconductor layer 20 may be formed by patterning this film into a prescribed configuration if necessary. Thereby, the third portion 20a and the fourth portion 20b are formed. A thickness t4 of the fourth portion 20b is thinner than a thickness t3 of the third portion 20a due to the anisotropy when forming the film used to form the second semiconductor layer 20.

In other words, in the semiconductor light emitting device 110 according to the embodiment, the thickness t1 of the first portion 30a along the stacking direction (the direction from the upper surface 10u of the first semiconductor layer 10 toward the upper surface 30u of the active layer 30) is thicker than the thickness t2 of the second portion 30b along the first direction (the direction from the side surface 10s of the first semiconductor layer 10 toward the side surface 30s of the second portion 30b). The thickness t3 of the third portion 20a along the stacking direction is thicker than the thickness t4 of the fourth portion 20b along the first direction.

In the case of such a relationship between the thicknesses, the first portion 30a and the second portion 30b can be considered to be formed by forming the active layer 30 to cover the upper surface 10u and the side surface 10s of the first semiconductor layer 10. Also, the third portion 20a and the fourth portion 20b can be considered to be formed by forming the film used to form the second semiconductor layer 20 to cover the upper surface 30u and the side surface 30s of the active layer 30. This film may be patterned into a prescribed configuration if necessary.

As illustrated in FIG. 1, the semiconductor light emitting device 110 further includes a first electrode 40, a second electrode 51, a second electrode pad 52, a support substrate 53, and an insulating layer 60. The first semiconductor layer 10 is disposed between the first electrode 40 and the support substrate 53. The third portion 20a of the second semiconductor layer 20 is disposed between the first semiconductor layer 10 and the support substrate 53. The second electrode 51 is disposed between the third portion 20a and the support substrate 53. The second electrode pad 52 is disposed between the second electrode 51 and the support substrate 53.

The first electrode 40 is electrically connected to the lower surface of the first semiconductor layer 10 (the surface on the side of the first semiconductor layer 10 opposite to the first portion 30a). The second electrode 51 is electrically connected to an upper surface 20u of the third portion 20a of the second semiconductor layer 20 (the surface on the side of the second semiconductor layer 20 opposite to the first portion 30a). The second electrode pad 52 electrically connects the second electrode 51 to the support substrate 53.

For example, the first electrode 40 may include, for example, various conductive materials. The second electrode 51 may include, for example, a stacked film of a Ni film and a Au film. The Ni film is provided, for example, on the third portion 20a of the second semiconductor layer 20. The Au film is provided on the Ni film. The second electrode pad 52 may include, for example, a stacked film of a Ti film, a Pt film, and a Au film. The Ti film is provided, for example, on the second electrode 51. The Pt film is provided on the Ti film. The Au film is provided on the Pt film. The support substrate 53 may include a conductive substrate. The support substrate 53 may include, for example, a metal plate and a semiconductor plate.

The insulating layer 60 covers a side surface of the third portion 20a. In this example, the insulating layer 60 extends over a portion of the first portion 30a of the active layer 30 (a portion of the active layer 30 not covered with the third portion 20a). The insulating layer 60 also extends over the fourth portion 20b of the second semiconductor layer 20. The insulating layer 60 may include, for example, ZrO.

FIG. 2 is a schematic cross-sectional view illustrating the configuration of a portion of the semiconductor light emitting device according to the first embodiment.

This drawing illustrates an example of the configuration of the active layer 30.

As illustrated in FIG. 2, the active layer 30 includes multiple barrier layers 31 and a well layer 32. The well layer 32 is provided between the multiple barrier layers 31. In this example, four barrier layers 31 and the three well layers 32 are provided. Each of the well layers 32 is disposed between the barrier layers 31. In other words, the active layer 30 may have a multiple quantum well (MQW) configuration.

The embodiment is not limited thereto. There may be one well layer 32. In other words, the active layer 30 may have a single quantum well (SQW) configuration.

As described above, the thickness t1 of the first portion 30a of the active layer 30 is thicker than the thickness t2 of the second portion 30b. For each of the barrier layers 31, the thickness of the portion included in the first portion 30a (the thickness along the stacking direction) is thicker than the thickness of the portion included in the second portion 30b (the thickness along the first direction). For the well layer 32, the thickness of the portion included in the first portion 30a (the thickness along the stacking direction) is thicker than the thickness of the portion included in the second portion 30b (the thickness along the first direction).

Light is emitted from the first portion 30a by a current flowing in the first portion 30a of the active layer 30 by applying a voltage between the first semiconductor layer 10 and the third portion 20a of the second semiconductor layer 20. This current substantially does not flow in the second portion 30b of the active layer 30. Therefore, light substantially is not emitted from the second portion 30b.

Thus, in the embodiment, the intensity of the light emitted from the second portion 30b is lower than the intensity of the light emitted from the first portion 30a. The intensity of the light emitted from the second portion 30b being lower than the intensity of the light emitted from the first portion 30a also includes the case where light substantially is not emitted from the second portion 30b.

As described below, the first semiconductor layer 10 is, for example, formed on a crystal film that is formed on a GaN substrate. The upper surface 10u of the first semiconductor layer 10 is, for example, a c-plane. Then, the upper surface 30u of the first portion 30a of the active layer 30 provided on the upper surface 10u of the first semiconductor layer 10 and the upper surface 20u of the third portion 20a of the second semiconductor layer 20 provided on the upper surface 30u are c-planes.

On the other hand, the side surface 30s of the second portion 30b and a side surface 20s of the fourth portion 20b that are provided along the side surface 10s of the first semiconductor layer 10 are, for example, planes perpendicular to the c-plane (e.g., an a-plane, an m-plane, and the like).

Thus, in the semiconductor light emitting device 110, the second portion 30b of the active layer 30 and the fourth portion 20b of the second semiconductor layer 20 are provided to oppose the side surface 10s of the first semiconductor layer 10. Thereby, a high insulative property is obtained at the side surface 10s of the first semiconductor layer 10. Thereby, a passivation film to cover the side surface 10s of the first semiconductor layer 10 can be omitted. Thereby, the processes can be simplified.

Thus, in the semiconductor light emitting device 110 according to the embodiment, an inexpensive and high-performance semiconductor light emitting device can be provided.

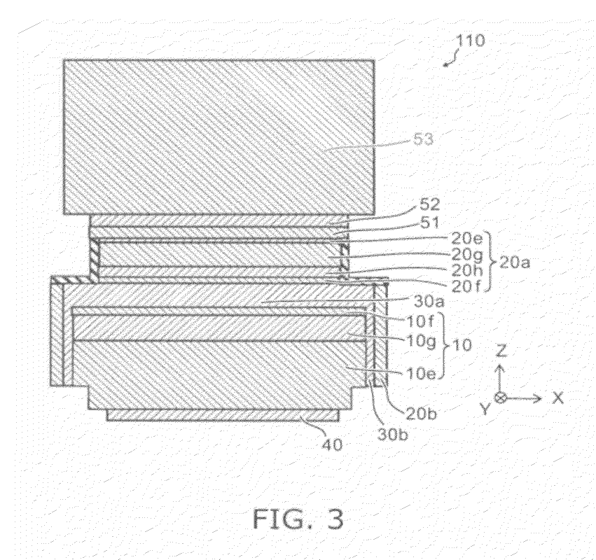

FIG. 3 is a schematic cross-sectional view illustrating the configuration of the semiconductor light emitting device according to the first embodiment. This drawing illustrates the configuration of one specific example of the semiconductor light emitting device 110 according to the embodiment.

As illustrated in FIG. 3, the first semiconductor layer 10 may include a first n-type layer 10e, a second n-type layer 10f, and a third n-type layer 10g. These layers are stacked along the Z-axis. The third n-type layer 10g is provided between the first n-type layer 10e and the second n-type layer 10f.

The first n-type layer 10e is, for example, a contact layer. The first n-type layer 10e may include, for example, an n-type GaN layer. The thickness of the first n-type layer 10e is, for example, 2 micrometers (μm).

The second n-type layer 10f is, for example, a guide layer. The second n-type layer 10f may include, for example, an In_{0.02}Ga_{0.98}N layer. The thickness of the second n-type layer 10f is, for example, 100 nanometers (nm) (for example, not less than 50 nm and not more than 150 nm).

The third n-type layer 10g is, for example, a clad layer. The third n-type layer 10g may include, for example, an n-type Al_{0.06}Ga_{0.94}N layer. The thickness of the third n-type layer 10g is, for example, 1.2 μm (for example, not less than 0.8 μm and not more than 1.6 μm).

The second semiconductor layer 20 may include a first p-type layer 20e, a second p-type layer 20f, a third p-type layer 20g, and a fourth p-type layer 20h. These layers are stacked along the Z-axis. The third p-type layer 20g is provided between the first p-type layer 20e and the second p-type layer 20f. The fourth p-type layer 20h is provided between the third p-type layer 20g and the second p-type layer 20f.

The first p-type layer 20e is, for example, a contact layer. The first p-type layer 20e may include, for example, a p-type

GaN layer. The thickness of the third portion 20a at the first p-type layer 20e is, for example, 10 nm (for example, not less than 5 nm and not more than 15 nm).

The second p-type layer 20f is, for example, an electron confinement layer. The second p-type layer 20f may include, for example, a p-type Al_{0.2}Ga_{0.8}N layer. The thickness of the second p-type layer 20f at the third portion 20a is, for example, 10 nm (for example, not less than 5 nm and not more than 15 nm).

The third p-type layer 20g is, for example, a clad layer. The third p-type layer 20g may include, for example, a p-type Al_{0.06}Ga_{0.94}N layer. The thickness of the third p-type layer 20g at the third portion 20a is, for example, 600 nm (for example, not less than 400 nm and not more than 800 nm).

The fourth p-type layer 20h is, for example, a guide layer. The fourth p-type layer 20h may include, for example, a p-type In_{0.02}Ga_{0.98}N layer. The thickness of the fourth p-type layer 20h at the third portion 20a is, for example, 100 nm (for example, not less than 50 nm and not more than 150 nm).

As described above, the thickness t4 of the fourth portion 20b of the second semiconductor layer 20 (the thickness along the X-axis) is thinner than the thickness t3 of the third portion 20a of the second semiconductor layer 20 (the thickness along the Z-axis). Accordingly, the thicknesses of the portions of the first p-type layer 20e, the second p-type layer 20f, the third p-type layer 20g, and the fourth p-type layer 20h recited above corresponding to the fourth portion 20b (the thicknesses along the X-axis) are thinner than the thicknesses of the portions corresponding to the third portion 20a (the thicknesses along the Z-axis).

In the semiconductor light emitting device 110, for example, an In_{0.2}Ga_{0.8}N layer may be used as the well layer 32. The thickness of the well layer 32 at the first portion 30a is, for example, 3 nm (for example, not less than 1.5 nm and not more than 5 nm). For example, an In_{0.03}Ga_{0.97}N layer may be used as the barrier layer 31. The thickness of the barrier layer 31 at the first portion 30a is, for example, 10 nm (for example, not less than 5 nm and not more than 15 nm). In this example, the number of the well layers 32 is three. The well layer 32 has an In composition ratio higher than an In composition in the barrier layer 31.

As described above, the thickness t2 of the second portion 30b of the active layer 30 (the thickness along the X-axis) is thinner than the thickness t1 of the first portion 30a of the active layer 30 (the thickness along the Z-axis). Accordingly, the thickness of the portion of the well layer 32 corresponding to the second portion 30b (the thickness along the X-axis) is thinner than the thickness of the portion of the well layer 32 corresponding to the first portion 30a (the thickness along the Z-axis). The thickness of the portion of the barrier layer 31 corresponding to the second portion 30b (the thickness along the X-axis) is thinner than the thickness of the portion of the barrier layer 31 corresponding to the first portion 30a (the thickness along the Z-axis).

One example of a method for manufacturing the semiconductor light emitting device 110 according to the embodiment will now be described.

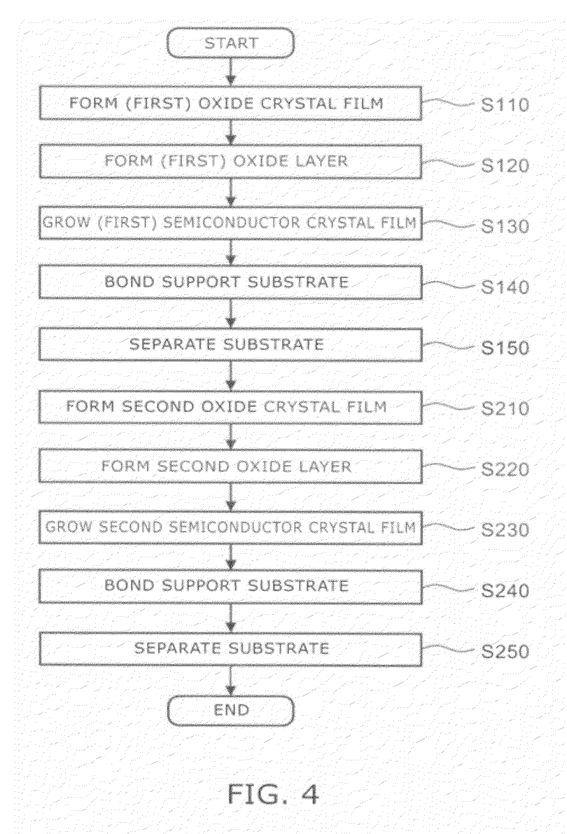

FIG. 4 is a flowchart illustrating the method for manufacturing the semiconductor light emitting device according to the first embodiment.

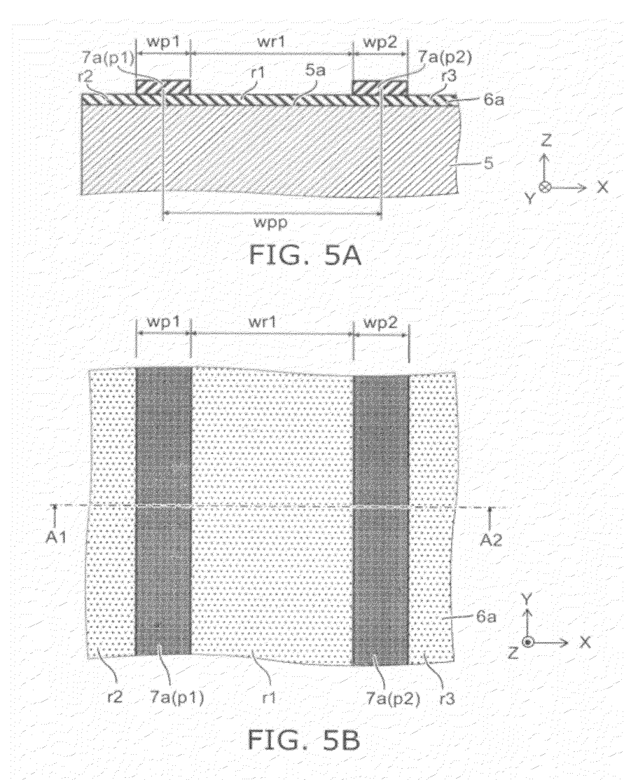

FIG. 5A and FIG. 5B are schematic views illustrating the method for manufacturing the semiconductor light emitting device according to the first embodiment.

Namely, FIG. 5B is a plan view. FIG. 5A is a cross-sectional view along line A1-A2 of FIG. 5B.

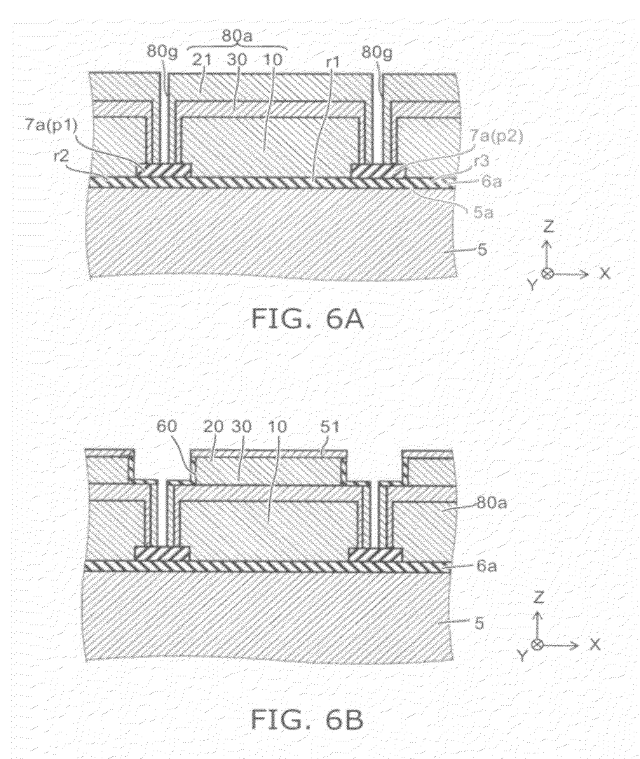

FIG. 6A, FIG. 6B, FIG. 7A, FIG. 7B, and FIG. 8 are schematic cross-sectional views in order of the processes, illustrating the method for manufacturing the semiconductor light emitting device according to the first embodiment.

These drawings correspond to the cross section along line A1-A2 of FIG. 5B.

As illustrated in FIG. 4, FIG. 5A, and FIG. 5B, the manufacturing method includes a process of forming an oxide crystal film (a first oxide crystal film 6a) on a major surface 5a of a substrate 5 of the nitride semiconductor (step S110). The substrate 5 is made of, for example, GaN.

For example, the major surface 5a of the substrate 5 is a c-plane of GaN. The first oxide crystal film 6a may include, for example, an oxide of at least one selected from Zn and Mg. For example, a ZnO film may be used as the first oxide crystal film 6a. The first oxide crystal film 6a is epitaxially grown on the major surface 5a of the substrate 5.

The manufacturing method further includes a process of forming an oxide layer (a first oxide layer 7a) that includes a first pattern portion p1 on a portion of the first oxide crystal film 6a (step S120).

The first oxide layer 7a may include, for example, an oxide of Si. The first oxide layer 7a may include, for example, a SiO₂ layer.

In this example, the first oxide layer 7a further includes a second pattern portion p2. The second pattern portion p2 is distal to the first pattern portion p1.

For example, the first pattern portion p1 and the second pattern portion p2 are formed by forming a film used to form the first oxide layer 7a on the first oxide crystal film 6a and subsequently patterning this film into a prescribed configuration. The first pattern portion p1 and the second pattern portion p2 are formed by forming a film used to form the first oxide layer 7a on the first oxide crystal film 6a by using a prescribed mask.

In the first oxide crystal film 6a, a first region r1 and a second region r2 are provided on two sides of the first pattern portion p1. In other words, the first pattern portion p1 is provided on the first oxide crystal film 6a between the first region r1 and the second region r2. The first region r1 is disposed between the first pattern portion p1 and the second pattern portion p2. The first oxide crystal film 6a further includes a third region r3. The second pattern portion p2 is disposed between the first region r1 and the third region r3.

As illustrated in FIG. 4 and FIG. 6A, the manufacturing method may further include a process of growing a semiconductor crystal film (a first semiconductor crystal film 80a) on the first region r1 and the second region r2 of the first oxide crystal film 6a which are disposed on the two sides of the first pattern portion p1 (step S130). The first semiconductor crystal film 80a has a crystal orientation reflecting the crystal orientation of the substrate 5. The first semiconductor crystal film 80a includes a nitride semiconductor. In other words, the first semiconductor crystal film 80a is epitaxially grown on the first region r1 and the second region r2 of the first oxide crystal film 6a.

For example, the first semiconductor crystal film 80a includes the first semiconductor layer 10, the active layer 30, and a crystal film 21 used to form the second semiconductor layer 20. In other words, the growth of the first semiconductor crystal film 80a includes growing the first semiconductor layer 10 of the first conductivity type on the first oxide crystal film 6a, growing the active layer 30 to cover the upper surface 10u and the side surface 10s of the first semiconductor layer 10, and growing the crystal film 21 used to form the second semiconductor layer 20 of the second conductivity type which is different from the first conductivity type to cover the upper surface 30u and the side surface 30s of the active layer 30.

At this time, as illustrated in FIG. 6A, the first semiconductor crystal film 80a is grown to make a gap 80g of the first semiconductor crystal film 80a on the first pattern portion p1 and the second pattern portion p2. It is sufficient for the gap 80g to be made on at least a portion of the first pattern portion p1 and at least a portion of the second pattern portion p2.

In other words, the process of growing the first semiconductor crystal film 80a includes making the gap 80g on the first pattern portion p1 between at least a portion of the first semiconductor crystal film 80a grown from the first region r1 and at least a portion of the first semiconductor crystal film 80a grown from the second region r2.

In this example, the process of growing the first semiconductor crystal film 80a includes growing the first semiconductor crystal film 80a on the third region r3. The process of growing the first semiconductor crystal film 80a includes making the gap 80g on the second pattern portion p2 between at least a portion of the first semiconductor crystal film 80a grown from the first region r1 and at least a portion of the first semiconductor crystal film 80a grown from the third region r3.

Thereby, discontinuous portions of the first semiconductor crystal film 80a are formed respectively on the first pattern portion p1 and the second pattern portion p2 of the first oxide layer 7a.

Subsequently, as illustrated in FIG. 6B, the second semiconductor layer 20 is formed by patterning the crystal film 21 used to form the second semiconductor layer 20 into a prescribed configuration. Thereby, for example, a ridge portion is formed. Then, the insulating layer 60 is formed. Further, the second electrode 51 is formed. This patterning of the crystal film 21 may be implemented if necessary and may be omitted in some cases.

Then, as illustrated in FIG. 7A, the second electrode pad 52 is formed on the second electrode 51. Continuing, the support substrate 53 is bonded to the second electrode pad 52. A hole 53h (a through-hole) is provided in the support substrate 53 to communicate with the gap 80g recited above.

In other words, as illustrated in FIG. 4, the manufacturing method may further include a process of forming an upper side electrode (the second electrode 51, the second electrode pad 52, and the like) on the upper surface of the first semiconductor crystal film 80a and bonding the support substrate 53 on the upper side electrode (step S140). Step S140 is implemented prior to step S150 recited below.

As illustrated in FIG. 4 and FIG. 7B, the manufacturing method may further include a process of separating the substrate 5 from the first semiconductor crystal film 80a (step S150) by removing the first oxide crystal film 6a and the first oxide layer 7a using wet processing via the gap 80g after the growth of the first semiconductor crystal film 80a (after step S130).

Subsequently, as illustrated in FIG. 8, the first electrode 40 is formed on the lower surface of the first semiconductor crystal film 80a (specifically, the lower surface of the first semiconductor layer 10). Subsequently, the semiconductor light emitting devices 110 are obtained by cutting the patterning body into a prescribed configuration.

Then, as illustrated in FIG. 4, another semiconductor light emitting device can be constructed using the substrate 5.

In other words, the manufacturing method may further include a process of forming a second oxide crystal film (e.g., the first oxide crystal film 6a of a second time) layer on the major surface 5a of the substrate 5 separated from the first semiconductor crystal film 80a (step S210).

Then, the manufacturing method may further include a process of forming a second oxide layer (e.g., the first oxide layer 7a of the second time) that has the third pattern portion on a portion of the second oxide crystal film (step S220). This third pattern portion may be, for example, the same pattern as that of the first pattern portion p1 or may be another pattern.

The manufacturing method may further include a process of growing a second semiconductor crystal film (e.g., the first semiconductor crystal film 80a of the second time) on a fourth region and a fifth region of the second oxide crystal film that are disposed on two sides of the second oxide layer (step S230). The second semiconductor crystal film has a crystal orientation reflecting the crystal orientation of the substrate 5 and includes a nitride semiconductor. The fourth region corresponds to, for example, the first region r1 of step S130. The fifth region corresponds to, for example, the second region r2 of step S130. However, the embodiment is not limited thereto. The fourth region may be different from the first region r1; and the fifth region may be different from the second region r2.

The process of growing the second semiconductor crystal film may include making the gap 80g on the third pattern portion recited above between at least a portion of the second semiconductor crystal film grown from the fourth region and at least a portion of the second semiconductor crystal film grown from the fifth region.

Then, as illustrated in FIG. 4, the manufacturing method may further include a process of forming an upper side electrode on the upper surface of the second semiconductor crystal film and bonding the support substrate 53 on the upper side electrode (step S240).

Continuing as illustrated in FIG. 4, the manufacturing method may further include a process of separating the substrate 5 from the second semiconductor crystal film by removing the second oxide crystal film and the second oxide layer by using wet processing via the gap 80g (step S250).

Thus, in the manufacturing method, semiconductor light emitting devices may be constructed by using the substrate 5 multiple times. Thereby, the semiconductor light emitting devices can be manufactured inexpensively. In the manufacturing method, a semiconductor layer having few defects and high crystallinity can be formed because the semiconductor light emitting device is formed on the substrate of a nitride semiconductor (e.g., GaN). Thereby, the performance of the semiconductor light emitting device that is manufactured is high. Thus, according to the manufacturing method according to the embodiment, a high-performance semiconductor light emitting device can be manufactured inexpensively.

In the manufacturing method, lattice mismatch occurs due to the difference between the lattice constant of the GaN and the lattice constant of the first oxide crystal film 6a (e.g., ZnO) in the case where, for example, the first oxide crystal film 6a is thicker than 20 nm. Good crystallinity is obtained by setting the thickness of the first oxide crystal film 6a to be not more than the critical film thickness.

From the aspect of the difference between the coefficients of thermal expansion of the first oxide crystal film 6a and the substrate 5 of the nitride semiconductor (e.g., GaN), it is desirable for the thickness of the first oxide crystal film 6a to be not less than 0.5 nm (1 monolayer) and not more than 100 nm.

From the description recited above, it is desirable for the thickness of the first oxide crystal film 6a (and the second oxide crystal film) to be, for example, not less than 0.5 nm and not more than 20 nm. Thereby, good crystallinity and good characteristics are obtained in which the warp caused by the difference between the coefficients of thermal expansion and the like are suppressed. Thereby, the crystal orientation of the semiconductor film grown on the first oxide crystal film 6a can stably reflect the crystal orientation of the substrate 5.

In the manufacturing method, the first semiconductor crystal film 80a is grown to make the gap 80g of the first semiconductor crystal film 80a on the first pattern portion p1 and the second pattern portion p2 of the first oxide layer 7a. Then, the gap 80g is utilized in the process of removing the substrate 5. The first semiconductor crystal film 80a grows easily on the first oxide crystal film 6a and does not grow easily on the first oxide layer 7a. Thereby, the gap 80g is made. The first oxide crystal film 6a and the first oxide layer 7a are selected to obtain such a characteristic.

In other words, for example, in the process of growing the first semiconductor crystal film 80a, the diffusion length of the source material of the first semiconductor crystal film 80a on the first oxide layer 7a is longer than the diffusion length of the source material of the first semiconductor crystal film 80a on the first oxide crystal film 6a. Thereby, the first semiconductor crystal film 80a grows less easily on the first oxide layer 7a than on the first oxide crystal film 6a. Thereby, the gap 80g is made more easily.

In the growth of the first semiconductor crystal film 80a, for example, the growth rate of the first semiconductor crystal film 80a in the vertical direction (the stacking direction perpendicular to the major surface 5a of the substrate 5, e.g., the Z-axis direction) may be set to be higher than the growth rate of the first semiconductor crystal film 80a in the lateral direction (a direction parallel to the major surface 5a, e.g., the X-axis direction). Thereby, the gap 80g is made more easily.

In the manufacturing method as illustrated in FIG. 5A and FIG. 5B, the width of the first region r1 is wider than the widths of the first pattern portion p1 and the second pattern portion p2. In the manufacturing method, the first region r1 is a region used to form the semiconductor light emitting device; and the first pattern portion p1 and the second pattern portion p2 are the regions between the multiple semiconductor light emitting devices. By setting the width of the first region r1 to be wide, the number of the semiconductor light emitting devices obtained from one substrate 5 increases.

Thus, in the embodiment, a width wr1 between the first pattern portion p1 and the second pattern portion p2 along the first direction (e.g., the X-axis direction) from the first pattern portion p1 toward the second pattern portion p2 (i.e., the width of the first region r1 along the X-axis direction) is wider than a width wp1 of the first pattern portion p1 along the first direction and is wider than a width wp2 of the second pattern portion p2 along the first direction.

For example, the width wr1 is not less than 20 μm and not more than 500 μm.

For example, the width wp1 (the width of the first pattern portion p1 along the X-axis direction) and the width wp2 (the width of the second pattern portion p2 along the X-axis direction) are not more than 15 μm. The width wp1 and the width wp2 are, for example, not less than 5 μm.

For example, the width wp1 and the width wp2 are 10 μm. The distance wpp along the X-axis direction from the center of the first pattern portion p1 along the X-axis direction to the center of the second pattern portion p2 along the X-axis direction (i.e., the disposition pitch between the first pattern portion p1 and the second pattern portion p2) is, for example, 40 μm. In such a case, the distance along the X-axis direction between the first pattern portion p1 and the second pattern portion p2 (corresponding to the width wr1 of the first region r1) is 30 μm.

In the case where the width wp1 (and the width wp2) is excessively narrow (e.g., less than 5 μm), the first semiconductor crystal film 80a grown from the first region r1 and the second region r2 may easily become continuous on the first pattern portion p1 according to the growth conditions of the first semiconductor crystal film 80a. Therefore, there are cases where the gap 80g is not made or the width of the gap 80g is excessively narrow. Therefore, the width wp1 (and the width wp2) is set to be not less than the width at which the gap 80g is made.

On the other hand, in the case where the width wp1 (and the width wp2) is excessively wide (e.g., exceeding 15 μm), constraints arise on the number of the semiconductor light emitting devices obtained from one substrate 5. Or, constraints arise on the size of the semiconductor light emitting device. Therefore, it is practically desirable for the width wp1 (and the width wp2) to be not more than 15 μm.

In the case where the width wp1 (and the width wp2) is larger than 15 μm, for example, there are cases where the photoresist cannot be uniformly coated due to surface tension when coating the photoresist when constructing the semiconductor light emitting device. Thereby, the pattern of the photoresist collapses; and the yield of the semiconductor light emitting device is extremely low. From this aspect as well, it is desirable for the width wp1 (and the width wp2) to be not more than 15 μm.

Although the distance wpp (the disposition pitch of the first pattern portion p1 and the second pattern portion p2) is 40 μm in the description recited above, the embodiment is not limited thereto. For example, it is desirable for the distance wpp to be not more than 100 μm. The distance wpp corresponds to about two times the distance from the center of the first portion 30a of the active layer 30 along the X-axis direction to the center of the second portion 30b of the active layer 30 along the first direction.

In other words, in the semiconductor light emitting device 110, it is desirable for the distance from the center of the first portion 30a along the X-axis direction to the center of the second portion 30b along the X-axis direction (½ of the distance wpp) to be not more than 50 μm. Thereby, the width of the first region r1 is set to be wide; and the number of the semiconductor light emitting devices obtained from one substrate 5 increases.

It is desirable for the distance from the center of the first portion 30a along the X-axis direction to the center of the second portion 30b along the X-axis direction to be not less than 15 μm. In other words, it is desirable for the distance wpp (the disposition pitch of the first pattern portion p1 and the second pattern portion p2) to be not less than 30 μm. Thereby, the gap 80g forms more easily on the first pattern portion p1 and the second pattern portion p2.

The distance recited above can be measured, for example, by viewing the cross section of the semiconductor light emitting device 110 using an electron microscope. The measurement method is arbitrary.

One example of the manufacturing method according to the embodiment will now be described.

The substrate 5 of the nitride semiconductor (e.g., GaN) is placed inside a molecular beam epitaxy (MBE) apparatus. The thickness of the substrate 5 is, for example, 400 μm. The substrate temperature is increased to 700° C. while irradiating nitrogen radicals. The nitrogen radicals are switched to oxygen radicals simultaneously with the opening of the shutter of a Zn source. Thereby, a ZnO film (the first oxide crystal film 6a) epitaxially grows on the major surface 5a of the substrate 5. The thickness of the ZnO film is about 10 nm (for example, not less than 5 nm and not more than 15 nm).

The shutter of the Zn source is closed and the substrate temperature is reduced while irradiating the oxygen radicals onto the substrate 5 until the substrate temperature reaches 500° C. When the substrate temperature is less than 500° C., the substrate temperature is reduced further without irradiating the oxygen radicals. After reducing the substrate temperature to room temperature, the substrate 5 is extracted from the MBE apparatus.

The extracted substrate 5 is placed inside a thermal CVD apparatus; and a SiO₂ film is formed on the ZnO film which is on the substrate 5. The thickness of the SiO₂ film is about 100 nm (for example, not less than 50 nm and not more than 150 nm). The substrate 5 is extracted from the thermal CVD apparatus.

The SiO₂ film is patterned using a photoresist. Specifically, the SiO₂ film is patterned into a pattern having a band configuration along a direction parallel to (1-100) of the GaN of the substrate 5. In this pattern, the width of the band of the SiO₂ film is 10 μm; and the period of the bands is 40 μm. A photoresist is formed on the SiO₂ film such that the SiO₂ film having a such a configuration remains. The SiO₂ film of the portion not covered with the photoresist is etched using the photoresist as a mask.

Thereby, as illustrated in FIG. 5A and FIG. 5B, a SiO₂ film having a stripe configuration (a band configuration) is obtained. After this patterning, the SiO₂ film becomes the first pattern portion p1, the second pattern portion p2, and the like.

Then, the substrate 5 is disposed inside an MOCVD apparatus. Continuing, the first semiconductor crystal film 80a is grown. At this time, the source material that is used may include, for example, trimethylgallium (TMG), trimethylaluminum (TMA), trimethylindium (TMI), bis(cyclopentadienyl)magnesium (Cp₂Mg), ammonia (NH₃), and silane (SiH₄). Hydrogen and nitrogen are used as the carrier gas.

Specifically, an n-type GaN layer is grown by, for example, heating the substrate 5 to 1000° C. and by using TMG, NH₃, and SiH₄. At this time, the n-type GaN layer is grown using nitrogen as the carrier gas with ammonia at 6 L/minute, TMG at 50 cc/minute, and SiH₄ at 10 cc/minute. The time of this growth is, for example, 10 minutes. Further, the n-type GaN layer is grown by introducing hydrogen and by using ammonia at 12 L/minute, TMG at 50 cc/minute, and SiH₄ at 10 cc/minute. Thereby, the lateral-direction growth rate on the SiO₂ film is controlled. The time of this growth is, for example, 70 minutes. By using this growth condition, a continuous first semiconductor crystal film 80a on the SiO₂ film is suppressed.

Subsequently, the active layer 30 is grown by adding TMI as a source material. For example, the flow rate of the TMI is adjusted such that the In concentration in the growth of the well layer 32 is 10% and the In concentration in the growth of the barrier layer 31 is 1%.

Then, a p-type GaN layer is grown by growing an AlGaN layer using TMA and by using Cp₂Mg as an impurity.

Thereby, as illustrated in FIG. 6A, the first semiconductor layer 10, the active layer 30, and the crystal film 21 used to form the second semiconductor layer 20 are formed.

In the case where the thickness of the GaN layer grown from the ZnO film (e.g., the first region r1, the second region r2, the third region r3, and the like) exceeds 100 nm in the growth of the first semiconductor layer 10 recited above, the GaN layer grows also in the lateral direction; and the GaN layer is formed also on the SiO₂ film. Although there are cases where the SiO₂ film contacts a portion of the GaN layer at this time, the SiO₂ film and the GaN layer are not bonded.

For example, in the case where the thickness of the GaN layer is 2 μm, the lateral-direction width of the GaN layer formed on the SiO₂ film (e.g., the width along the X-axis direction) is about 4.9 μm. In other words, a GaN layer having a width of 4.9 μm covers the first pattern portion p1 from two sides of the first pattern portion p1 of the SiO₂ film. Although there are cases where the opening on the first pattern portion p1 (the SiO₂ film) is filled by the subsequent growth of the first semiconductor crystal film 80a, the first semiconductor crystal film 80a does not bond and a gap 80g for which wet etching is possible remains on the first pattern portion p1. In other words, the gap 80g is made.

After the crystal growth, the substrate temperature is reduced and the substrate 5 is extracted from the MOCVD apparatus.

The substrate 5 is disposed inside a thermal CVD apparatus; and a SiO₂ film used as a mask is deposited with a thickness of about 900 nm (for example, not less than 800 nm and not more than 1000 nm). Subsequently, a photoresist is formed on the SiO₂ film; and the photoresist is patterned into a stripe configuration having a width of 20 μm. Multiple photoresists having the stripe configurations are formed, for example, on the first region r1 (and the second region r2 and the third region r3). In other words, the positions of the first pattern portion p1 and the second pattern portion p2 correspond to the positions of the portions between the multiple photoresists having the stripe configurations. The SiO₂ film which is used as a mask is patterned using dry etching by using this photoresist as a mask.

After peeling this photoresist, a portion of the second semiconductor layer 20 (the first to fourth p-type layers 20e to 20h) is removed using dry etching by using the patterned SiO₂ film as a mask. Thereby, a ridge configuration is formed. Subsequently, the SiO₂ film used as the mask is removed.

A ZrO₂ film used to form the insulating layer 60 is formed using an electron beam vapor deposition apparatus. A photoresist having openings positioned above the ridge portions is formed on the ZrO₂ film. A portion of the ZrO₂ film is removed by etching using this photoresist as a mask. Thereby, the portions of the ZrO₂ film positioned above the ridge portions are removed. Thereby, the insulating layer 60 is formed.

Subsequently, the substrate 5 is disposed inside an electron beam vapor deposition apparatus; a Ni film is deposited; and a Au film is deposited. The substrate 5 is extracted from the electron beam vapor deposition apparatus; and the Ni film and the Au film on the photoresist are removed while removing the photoresist using lift-off. The Ni film and the Au film remain in the region where the ZrO₂ film was etched.

Thereby, as illustrated in FIG. 6B, the second electrode 51 is formed.

The substrate 5 is disposed in an annealing oven; and annealing is performed in an oxygen atmosphere at 450° C. for 1 minute.

Subsequently, a resist pattern having an opening having a width of 35 μm and a length of 550 μm is formed on the patterning body. This opening is multiply provided along the X-axis direction and the Y-axis direction. Subsequently, the patterning body is disposed inside an electron beam vapor deposition apparatus; and a Ti film, a Pt film, and a Au film are deposited on the surface of the patterning body on the second electrode 51 side.

The patterning body is extracted from the electron beam vapor deposition apparatus; and the Ti film, the Pt film, and the Au film on the resist pattern are removed while removing the resist pattern using lift-off. Thereby, the second electrode pad 52 having a stacked structure of a Ti film, a Pt film, and a Au film is formed in the opening recited above. In other words, the multiple second electrode pads 52 are provided along the X-axis direction and the Y-axis direction.

Subsequently, as illustrated in FIG. 7A, the second electrode pad 52 and the support substrate 53 are bonded. The size of the support substrate 53 (the length and the width when viewed along the Z-axis direction) is, for example, the same as the size of the substrate 5. The hole 53h is provided in the support substrate 53. The hole 53h has a portion that overlays the first pattern portion p1 (and the second pattern portion p2) provided on the major surface 5a of the substrate 5 when viewed along the Z-axis direction. The support substrate 53 may include, for example, a copper plate on which Au plating is provided and the like. For example, a AuSn solder layer is provided on the bonding surface of the support substrate 53. For example, the AuSn solder layer has a portion that overlays the second electrode pad 52 when viewed along the Z-axis direction.

As illustrated in FIG. 7A, the second electrode pad 52 and the AuSn layer of the support substrate 53 are bonded by causing the second electrode pad 52 and the AuSn solder layer of the support substrate 53 to oppose each other and by heating. The temperature at this time is, for example, 250° C.

Subsequently, as illustrated in FIG. 7B, the patterning body is immersed in, for example, a solution including NH₄F and hydrochloric acid. Thereby, the SiO₂ film (the first pattern portion p1 and the second pattern portion p2) and the ZnO film (the first oxide crystal film 6a) are removed by etching via the hole 53h of the support substrate 53 and the gap 80g. Thereby, the substrate 5 is separated from the first semiconductor crystal film 80a.

Thus, in the manufacturing method, the ZnO film is formed on the major surface 5a of the substrate 5; and the substrate 5 can be separated by the ZnO film being removed without damaging the major surface 5a of the substrate 5. The substrate 5 can be re-utilized.

After peeling the substrate 5, the first semiconductor crystal film 80a is held by the support substrate 53. The support substrate 53 is subdivided along the hole 53h. The first semiconductor crystal film 80a is subdivided along the Y-axis direction. In other words, the first semiconductor crystal film 80a is divided by cleavage between the second electrode pads 52 provided along the Y-axis direction. Thereby, the semiconductor light emitting device 110 is constructed.

The semiconductor light emitting device 110 thus constructed has a width (a width along the X-axis direction) of 40 μm, a length (a length along the Y-axis direction) of 600 μm, and a height (a height along the Z-axis direction) of 500 μm. On the other hand, a semiconductor light emitting device of a reference example that does not use the manufacturing method recited above has, for example, a width of 400 μm, a length of 600 μm, and a height of 100 μm. Thus, the semiconductor light emitting device 110 constructed using the manufacturing method according to the embodiment has a narrower width than that of the semiconductor light emitting device of the reference example. Therefore, handling is possible in which the position of the handling in the manufacturing processes of the semiconductor light emitting device 110 according to the embodiment is changed from the position of the handling in the case of the reference example. Thereby, the handling is easier.

Because the width of the semiconductor light emitting device 110 according to the embodiment is narrower than that of the reference example, more semiconductor light emitting devices can be constructed from one substrate 5 than in the reference example. For example, the number of the semiconductor light emitting devices that can be constructed from one substrate 5 in the embodiment is, for example, 10 times that of the case of the reference example.

In the semiconductor light emitting device 110 as described above, the side surface of the first semiconductor layer 10 is covered with the active layer 30 and the second semiconductor layer 20. Thereby, the passivation film can be omitted because the surface conduction is extremely small.

Damage of the surface of the substrate 5 separated from the first semiconductor crystal film 80a is suppressed.

On the other hand, in the case of a reference example in which the substrate 5 is separated from the semiconductor crystal film using another method, an unevenness undesirably is formed in the surface of the substrate 5. Therefore, in the reference example, processing of the substrate 5 such as polishing and the like is necessary in the case where the substrate 5 is to be re-utilized.

For example, there exists a method for manufacturing a reference example in which multiple semiconductor light emitting devices are formed by forming a semiconductor crystal film on the substrate 5 and patterning the semiconductor crystal film. Practically, in this method, an unevenness undesirably is formed in the surface of the substrate 5 during this patterning. Even in the case where an oxide layer is formed on the substrate 5 and a semiconductor crystal film is grown on the oxide layer, the control of the etching process is difficult; and as expected, the unevenness is formed in the substrate 5.

Although it is possible that the margin of the etching process may increase in the case where, for example, the thickness of the oxide layer on the substrate 5 is increased, defects occur easily in the semiconductor crystal film grown on the oxide layer due to distortion and/or thermal expansion differences.

Conversely, in the embodiment, the substrate 5 can be re-utilized easily because the damage of the surface of the substrate 5 is suppressed.

### Second Embodiment

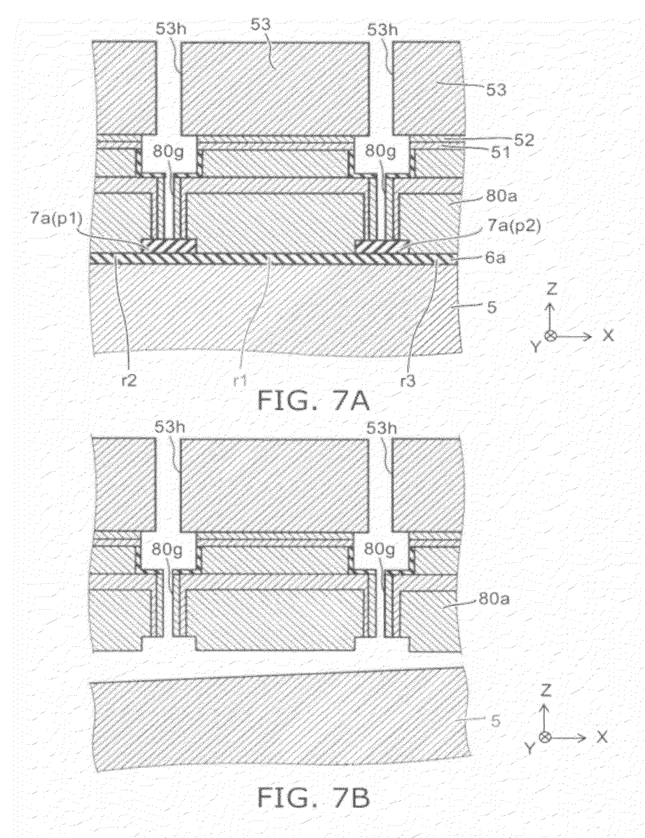

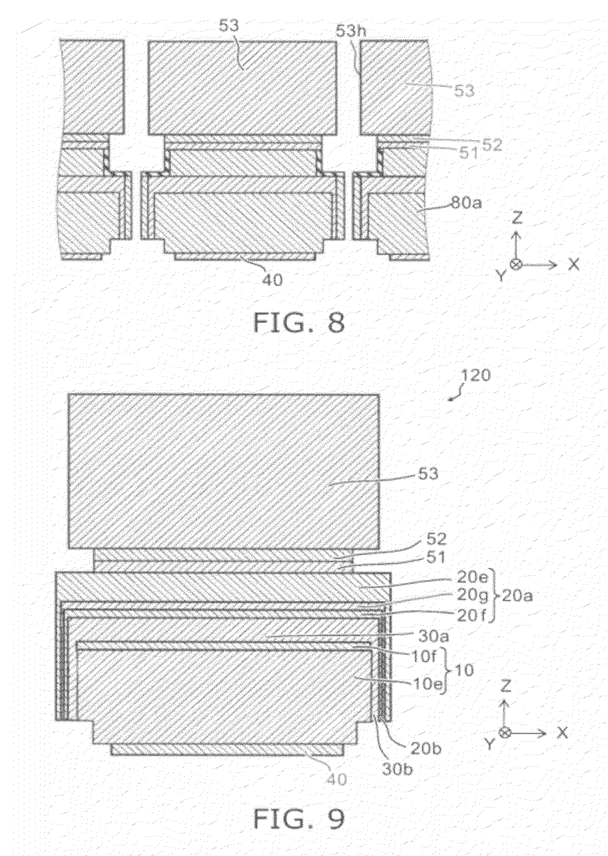

FIG. 9 is a schematic cross-sectional view illustrating the configuration of a semiconductor light emitting device according to a second embodiment. As illustrated in FIG. 9, the semiconductor light emitting device 120 according to the embodiment also includes the first semiconductor layer 10, the second semiconductor layer 20, and the active layer 30. The semiconductor light emitting device 120 of the specific example is an LED.

The portions of the semiconductor light emitting device 120 that differ from those of the semiconductor light emitting device 110 will now be described.

In the semiconductor light emitting device 120, the first semiconductor layer 10 includes the first n-type layer 10e and the second n-type layer 10f. These layers are stacked along the Z-axis.

The first n-type layer 10e is, for example, a contact layer. The first n-type layer 10e may include, for example, an n-type GaN layer. The thickness of the first n-type layer 10e is, for example, 2 μm.

The second n-type layer 10f may include, for example, an In_{0.02}Ga_{0.98}N layer. The thickness of the second n-type layer 10f is, for example, 10 nm (for example, not less than 5 nm and not more than 15 nm).

The second semiconductor layer 20 includes the first p-type layer 20e, the second p-type layer 20f, and the third p-type layer 20g. Portions of these layers corresponding to the third portion 20a are stacked along the Z-axis. Portions of these layers corresponding to the fourth portion 20b are stacked along the X-axis. The third p-type layer 20g is provided between the first p-type layer 20e and the second p-type layer 20f.

The first p-type layer 20e is, for example, a contact layer. The first p-type layer 20e may include, for example, a p-type GaN layer. The thickness of the third portion 20a of the first p-type layer 20e is, for example, 80 nm (for example, not less than 60 nm and not more than 100 nm).

The second p-type layer 20f is, for example, an electron confinement layer. The second p-type layer 20f may include, for example, a p-type Al_{0.2}Ga_{0.8}N layer. The thickness of the second p-type layer 20f at the third portion 20a is, for example, 10 nm (for example, not less than 5 nm and not more than 15 nm).

The third p-type layer 20g may include, for example, a p-type In_{0.02}Ga_{0.98}N layer. The thickness of the third p-type layer 20g at the third portion 20a is, for example, 10 nm (for example, not less than 5 nm and not more than 15 nm).

In the semiconductor light emitting device 120, a ridge portion is not provided.

The configuration of the active layer 30 of the semiconductor light emitting device 120 is similar to the configuration of the active layer 30 of the semiconductor light emitting device 110.

In the semiconductor light emitting device 120 as well, the second portion 30b of the active layer 30 and the fourth portion 20b of the second semiconductor layer 20 are provided to oppose the side surface 10s of the first semiconductor layer 10. Thereby, a high insulative property can be obtained at the side surface 10s of the first semiconductor layer 10; and the passivation film to cover the side surface 10s of the first semiconductor layer 10 can be omitted.

Thus, in the semiconductor light emitting device 120 according to the embodiment as well, an inexpensive and high-performance semiconductor light emitting device can be provided.

The semiconductor light emitting device 120 also can be manufactured using the manufacturing method illustrated in FIG. 4. In other words, the first oxide crystal film 6a is formed on the major surface 5a of the substrate 5 of the nitride semiconductor (e.g., GaN) (step S110); and the first oxide layer 7a that includes the first pattern portion p1 is formed on a portion of the first oxide crystal film 6a (step S120). The thickness of the substrate 5 is, for example, 400 μm. In this example, the thickness of the first oxide crystal film 6a is, for example, 5 nm (for example, not less than 3 nm and not more than 7 nm). The thickness of the first oxide layer 7a is, for example, 100 nm (for example, not less than 50 nm and not more than 150 nm).

In such a case, the planar pattern of the first oxide layer 7a may be modified from that of the semiconductor light emitting device 110.

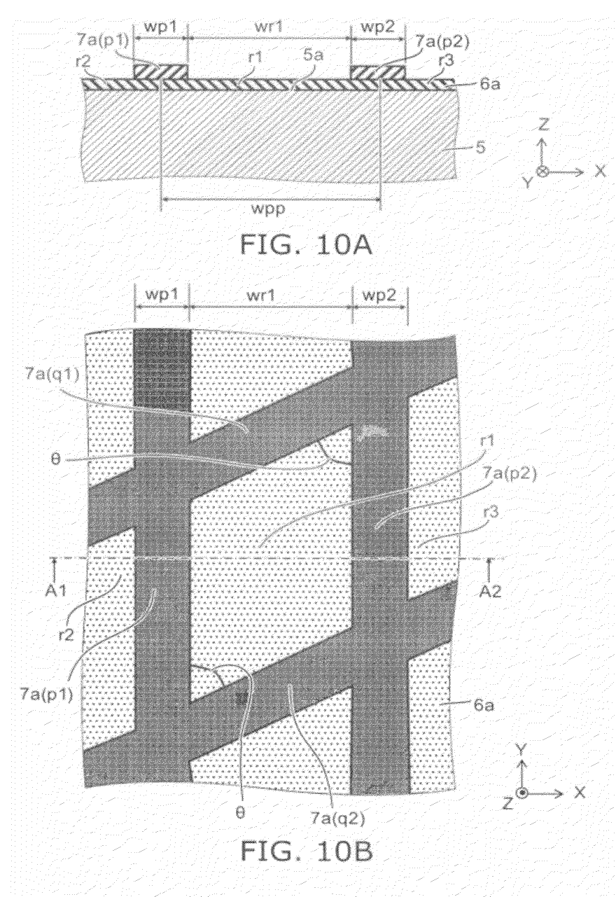

FIG. 10A and FIG. 10B are schematic views illustrating the method for manufacturing the semiconductor light emitting device according to the second embodiment.

Namely, FIG. 10B is a plan view illustrating one process. FIG. 10A is a cross-sectional view along line A1-A2 of FIG. 10B.

As illustrated in FIG. 10A and FIG. 10B, the first oxide layer 7a includes a first cross pattern portion q1 and a second cross pattern portion q2 in addition to the first pattern portion p1 and the second pattern portion p2 that extend in the Y-axis direction. The first cross pattern portion q1 and the second cross pattern portion q2 intersect the first pattern portion p1 and the second pattern portion p2. Thereby, the periphery of the first region r1 is subdivided by these pattern portions.

The angle θ between the first cross pattern portion q1 and the first pattern portion p1 and the angle θ between the first cross pattern portion q1 and the second pattern portion p2 are 60 degrees. The angle θ between the second cross pattern portion q2 and the first pattern portion p1 and the angle θ between the second cross pattern portion q2 and the second pattern portion p2 are 60 degrees.

For example, the Y-axis direction in which the first pattern portion p1 and the second pattern portion p2 extend is a direction parallel to (1-100) of the GaN crystal of the substrate 5. On the other hand, the direction in which the first cross pattern portion q1 and the second cross pattern portion q2 extend is a direction parallel to (0-110) of the GaN crystal. Herein, a direction perpendicular to the direction in which the first cross pattern portion q1 and the second cross pattern portion q2 extend and perpendicular to the Z-axis is taken as a cross arrangement direction.

The widths (the widths perpendicular to the X-axis direction) of the first pattern portion p1 and the second pattern portion p2 are 10 μm each. The distance (the pitch) along the X-axis direction from the center of the first pattern portion p1 along the X-axis direction to the center of the second pattern portion p2 along the X-axis direction is, for example, 100 μm.

The widths (the widths along the cross arrangement direction) of the first cross pattern portion q1 and the second cross pattern portion q2 are 10 μm each. The distance (the pitch) along the cross arrangement direction from the center of the first cross pattern portion q1 along the cross arrangement direction to the center of the second cross pattern portion q2 along the cross arrangement direction is, for example, 100 μm.

The first region r1 is a parallelogram having angles of 60 degrees or 120 degrees.

Thus, in the embodiment, the configuration of the first region r1 is a polygon having angles of 60 degrees or 120 degrees as viewed from a direction (the Z-axis direction) perpendicular to the major surface 5a of the substrate 5.

After forming the first oxide layer 7a having such a planar configuration, the processes described in regard to the first embodiment are implemented.

In other words, as described in regard to FIG. 6A, the first semiconductor crystal film 80a is grown on the first region r1 and the second region r2 of the first oxide crystal film 6a that are disposed on the two sides of the first pattern portion p1 (step S130). The first semiconductor crystal film 80a has a crystal orientation reflecting the crystal orientation of the substrate 5 and includes a nitride semiconductor. In such a case as well, the gap 80g is made on the first pattern portion p1 between at least a portion of the first semiconductor crystal film 80a grown from the first region r1 and at least a portion of the first semiconductor crystal film 80a grown from the second region r2.

Then, step S140 and step S150 described in regard to FIG. 6B, FIG. 7A, FIG. 7B, FIG. 8 are implemented.

In this example, the hole 53h of the support substrate 53 is provided to communicate with, for example, at least a portion of the first pattern portion p1, the second pattern portion p2, the first cross pattern portion q1, and the second cross pattern portion q2. After separating the substrate 5 from the first semiconductor crystal film 80a, the support substrate 53 is subdivided along the hole 53h. Thereby, the semiconductor light emitting device 120 can be formed.

Then, step S210 to step S220 may be implemented by re-utilizing the separated substrate 5.

Thus, according to the semiconductor light emitting device 120 and the method for manufacturing the semiconductor light emitting device 120 according to the embodiment, an inexpensive and high-performance semiconductor light emitting device and a method for manufacturing the semiconductor light emitting device are provided.

In a semiconductor light emitting device of a reference example in which an LED is constructed on a sapphire substrate, lattice matching between the sapphire substrate and the semiconductor layer is not performed. Therefore, in this reference example, crystal defects of about 1×10⁸ cm⁻² exist and cause the luminous efficiency to decrease.

Conversely, in the embodiment, the semiconductor light emitting device is formed on the substrate 5 of the nitride semiconductor (e.g., GaN). Therefore, the crystal defects of the semiconductor layer are not more than about 1×10⁶ cm⁻² and are extremely few. Also, the thermal conductivity of the semiconductor light emitting device according to the embodiment is high. Thereby, a semiconductor light emitting device having excellent characteristics can be provided. In the embodiment, the productivity is high and the manufacturing cost can be reduced because the substrate 5 of GaN used in the crystal growth is easily re-utilizable.

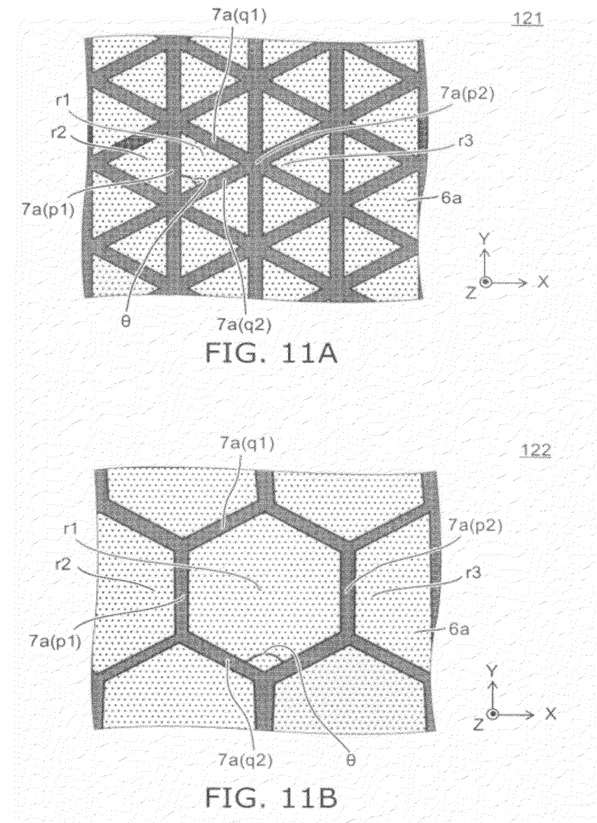

FIG. 11A and FIG. 11B are schematic plan views illustrating another method for manufacturing the semiconductor light emitting device according to the second embodiment.

These drawings illustrate the process of a portion of the method for manufacturing semiconductor light emitting devices 121 and 122 according to the embodiment and illustrate the planar pattern of the first oxide layer 7a.

In the manufacturing of the semiconductor light emitting device 121 as illustrated in FIG. 11A, the planar pattern (the pattern when viewed along the Z-axis direction) of the first oxide crystal film 6a exposed from the first oxide layer 7a is a triangle. The triangle has angles of 60 degrees. In other words, for example, the first region r1, the second region r2, and the third region r3 are triangles. One side of the triangle is, for example, parallel to (1-100) of the substrate 5 of the nitride semiconductor (e.g., GaN). One side of the triangle is, for example, parallel to (0-110) of the substrate 5.

In the manufacturing of the semiconductor light emitting device 122 as illustrated in FIG. 11B, the planar pattern of the first oxide crystal film 6a exposed from the first oxide layer 7a is a hexagon. The hexagon has angles of 120 degrees. In other words, for example, the first region r1, the second region r2, and the third region r3 are hexagons. One side of the hexagon is, for example, parallel to (1-100) of the substrate 5 of the nitride semiconductor (e.g., GaN). One side of the hexagon is, for example, parallel to (0-110) of the substrate 5.

Thus, in the embodiment, the configuration of the first region r1 is a polygon having angles of 60 degrees or 120 degrees as viewed from a direction perpendicular to the major surface 5a. More specifically, it is desirable for the first region r1 to be one selected from a triangle having an angle of 60 degrees, a parallelogram having an angle of 60 degrees, and a hexagon having an angle of 120 degrees. Thereby, the crystal orientation of the substrate 5, which is a hexagonal crystal, is parallel to the end surface of the semiconductor light emitting device that is formed; and the semiconductor light emitting device is made more easily.

### Third Embodiment

A third embodiment relates to a wafer.

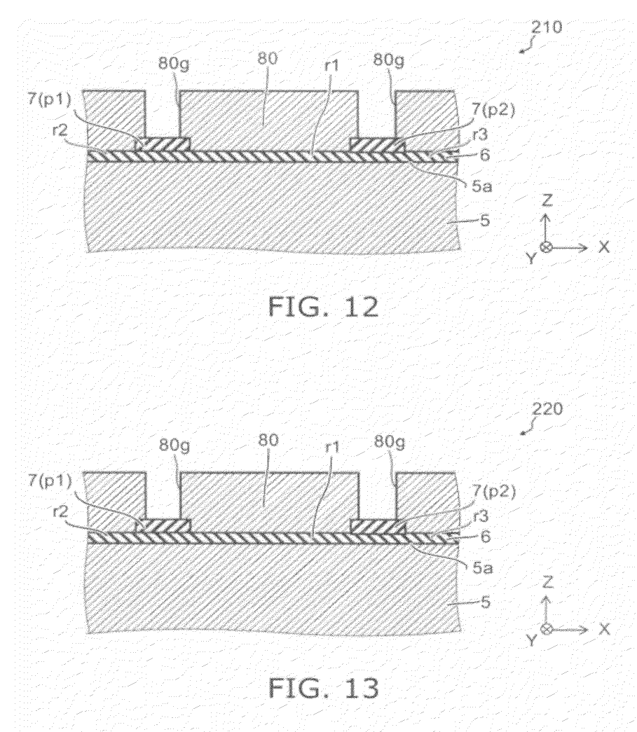

FIG. 12 is a schematic cross-sectional view illustrating the configuration of the wafer according to the third embodiment.

As illustrated in FIG. 12, a wafer 210 according to the embodiment includes the substrate 5, an oxide crystal film 6, an oxide layer 7, and a semiconductor crystal film 80.

The substrate 5 includes a nitride semiconductor (e.g., GaN). The substrate 5 is a single crystal. The oxide crystal film 6 is provided on the major surface 5a of the substrate 5. The oxide crystal film 6 may include the first oxide crystal film 6a described in regard to the first embodiment.

The oxide layer 7 is provided on a portion of the oxide crystal film 6. The oxide layer 7 includes the first pattern portion p1. The oxide layer 7 may include the first oxide layer 7a described in regard to the first embodiment.

The semiconductor crystal film 80 is provided on the first region r1 and the second region r2 of the oxide crystal film 6 that are disposed on two sides of the first pattern portion p1. The semiconductor crystal film 80 has a crystal orientation reflecting the crystal orientation of the substrate 5 and includes a nitride semiconductor. The semiconductor crystal film 80 may include the first semiconductor crystal film 80a described in regard to the first embodiment.

The semiconductor crystal film 80 has the gap 80g provided on the first pattern portion p1 between at least a portion of the semiconductor crystal film 80 grown from the first region r1 and at least a portion of the semiconductor crystal film 80 grown from the second region r2.

Thereby, a wafer can be provided to form an inexpensive and high-performance semiconductor light emitting device. The semiconductor crystal film 80 is, for example, the n type. In other words, the semiconductor crystal film 80 may include the first semiconductor layer 10. However, the semiconductor crystal film 80 may be non-doped. In other words, the semiconductor light emitting device may be constructed by further forming the first semiconductor layer 10, the active layer 30, and the second semiconductor layer 20 on the semiconductor crystal film 80.

The semiconductor crystal film 80 may include the first semiconductor layer 10, the active layer 30, and the second semiconductor layer 20. In such a case, the thickness t1 of the first portion 30a along the stacking direction (a direction perpendicular to the interface between the substrate 5 and the first semiconductor layer 10, e.g., the Z-axis direction) is thicker than the thickness t2 of the second portion 30b along the first direction (e.g., the X-axis direction) from the side surface 10s of the first semiconductor layer 10 toward the side surface 30s of the second portion 30b. The thickness t3 of the third portion 20a along the stacking direction is thicker than the thickness t4 of the fourth portion 20b along the first direction. The method for manufacturing the wafer according to the embodiment may include step S110 to S150 described above. The method for manufacturing may further include step S210 to S250 described above.

Thereby, a wafer can be manufactured efficiently to form an inexpensive and high-performance semiconductor light emitting device.

There are many defects in devices of reference examples that use an inexpensive sapphire substrate. On the other hand, other reference examples that use a GaN substrate have few defects but are expensive. It is difficult to manufacture an inexpensive device having few defects.

In the embodiment as recited above, the first oxide crystal film 6a (e.g., a zinc oxide film) is epitaxially grown on the major surface 5a of the substrate 5 of the nitride semiconductor (e.g., GaN). The thickness of the first oxide crystal film 6a is set to be a thickness not affected by the distortion due to differences between the lattice constants and the coefficients of thermal expansion of the substrate 5 and the first oxide crystal film 6a. The thickness of the first oxide crystal film 6a is, for example, about 10 nm (for example, not less than 0.5 nm and not more than 20 nm).

Subsequently, the first oxide layer 7a (e.g., a SiO₂ film) is formed on a portion of the first oxide crystal film 6a. Specifically, for example, the first oxide layer 7a is formed by forming a SiO₂ film on the first oxide crystal film 6a and patterning the SiO₂ film into a prescribed configuration. A portion of the first oxide crystal film 6a is exposed from the first oxide layer 7a.

Subsequently, a nitride semiconductor layer (e.g., a GaN layer) is grown as the first semiconductor crystal film 80a on a portion of the first oxide crystal film 6a. At this time, the GaN layer grows from the first oxide crystal film 6a and does not grow on the SiO₂ film. Then, the layer structure of the semiconductor light emitting device is formed. At this time, the gap 80g (the opening) remains on the SiO₂ film.

Thereby, the first oxide layer 7a and the first oxide crystal film 6a can be easily removed without needing to control the etching of the first oxide layer 7a and the first oxide crystal film 6a with high precision. Thereby, a nitride semiconductor layer in which the occurrence of crystal defects is suppressed is obtained. At this time, the formation of a recessed configuration in the substrate 5 of GaN is suppressed; and the surface of the substrate 5 is flat. Thereby, for example, polishing of the substrate 5 is unnecessary. Thereby, the substrate 5 can be re-utilized with high productivity. Thus, according to the embodiment, a device having high quality can be formed on the substrate 5 of the nitride semiconductor (e.g., GaN); the substrate 5 can be efficiently peeled; and the substrate 5 can be re-utilized easily after the peeling.

### Fourth Embodiment

A Fourth embodiment relates to a wafer.

FIG. 13 is a schematic cross-sectional view illustrating the configuration of the wafer according to the fourth embodiment.

As illustrated in FIG. 13, a wafer 220 according to the embodiment includes the substrate 5, an oxide crystal film 6, an oxide layer 7, and a semiconductor crystal film 80.

The substrate 5 includes a semiconductor (e.g., Si). The substrate 5 is a single crystal. The oxide crystal film 6 is provided on the major surface 5a of the substrate 5. The oxide crystal film 6 may include the first oxide crystal film 6a described in regard to the first embodiment.

The oxide layer 7 is provided on a portion of the oxide crystal film 6. The oxide layer 7 includes the first pattern portion p1. The oxide layer 7 may include the first oxide layer 7a described in regard to the first embodiment.

The semiconductor crystal film 80 is provided on the first region r1 and the second region r2 of the oxide crystal film 6 that are disposed on two sides of the first pattern portion p1. The semiconductor crystal film 80 has a crystal orientation reflecting the crystal orientation of the substrate 5 and includes a nitride semiconductor. The semiconductor crystal film 80 may include the first semiconductor crystal film 80a described in regard to the first embodiment.

The semiconductor crystal film 80 has the gap 80g provided on the first pattern portion p1 between at least a portion of the semiconductor crystal film 80 grown from the first region r1 and at least a portion of the semiconductor crystal film 80 grown from the second region r2.

Thereby, a wafer can be provided to form an inexpensive and high-performance semiconductor light emitting device. The semiconductor crystal film 80 is, for example, the n type. In other words, the semiconductor crystal film 80 may include the first semiconductor layer 10. However, the semiconductor crystal film 80 may be non-doped. In other words, the semiconductor light emitting device may be constructed by further forming the first semiconductor layer 10, the active layer 30, and the second semiconductor layer 20 on the semiconductor crystal film 80.

The semiconductor crystal film 80 may include the first semiconductor layer 10, the active layer 30, and the second semiconductor layer 20. In such a case, the thickness t1 of the first portion 30a along the stacking direction (a direction perpendicular to the interface between the substrate 5 and the first semiconductor layer 10, e.g., the Z-axis direction) is thicker than the thickness t2 of the second portion 30b along the first direction (e.g., the X-axis direction) from the side surface 10s of the first semiconductor layer 10 toward the side surface 30s of the second portion 30b. The thickness t3 of the third portion 20a along the stacking direction is thicker than the thickness t4 of the fourth portion 20b along the first direction.

The method for manufacturing the wafer according to the embodiment may include step S110 to S150 described above. The method for manufacturing may further include step S210 to S250 described above.

Thereby, a wafer can be manufactured efficiently to form an inexpensive and high-performance semiconductor light emitting device.

There are many defects in devices of reference examples that use an inexpensive sapphire substrate. On the other hand, other reference examples that use a GaN substrate have few defects but are expensive. It is difficult to manufacture an inexpensive device having few defects.

In the embodiment as recited above, the first oxide crystal film 6a (e.g., a zinc oxide film) is epitaxially grown on the major surface 5a of the substrate 5 of the semiconductor (e.g., Si). The thickness of the first oxide crystal film 6a is set to be a thickness not affected by the distortion due to differences between the lattice constants and the coefficients of thermal expansion of the substrate 5 and the first oxide crystal film 6a. The thickness of the first oxide crystal film 6a is, for example, about 10 nm (for example, not less than 0.5 nm and not more than 20 nm).

Subsequently, the first oxide layer 7a (e.g., a SiO₂ film) is formed on a portion of the first oxide crystal film 6a. Specifically, for example, the first oxide layer 7a is formed by forming a SiO₂ film on the first oxide crystal film 6a and patterning the SiO₂ film into a prescribed configuration. A portion of the first oxide crystal film 6a is exposed from the first oxide layer 7a.

Subsequently, a nitride semiconductor layer (e.g., a GaN layer) is grown as the first semiconductor crystal film 80a on a portion of the first oxide crystal film 6a. At this time, the GaN layer grows from the first oxide crystal film 6a and does not grow on the SiO₂ film. Then, the layer structure of the semiconductor light emitting device is formed. At this time, the gap 80g (the opening) remains on the SiO₂ film.

Thereby, the first oxide layer 7a and the first oxide crystal film 6a can be easily removed without needing to control the etching of the first oxide layer 7a and the first oxide crystal film 6a with high precision. Thereby, a nitride semiconductor layer in which the occurrence of crystal defects is suppressed is obtained. At this time, the formation of a recessed configuration in the substrate 5 of Si is suppressed; and the surface of the substrate 5 is flat. Thereby, for example, polishing of the substrate 5 is unnecessary. Thereby, the substrate 5 can be re-utilized with high productivity. Thus, according to the embodiment, a device having high quality can be formed on the substrate 5 of the semiconductor (e.g., Si); the substrate 5 can be efficiently peeled; and the substrate 5 can be re-utilized easily after the peeling.

According to the embodiment, an inexpensive and high-performance semiconductor light emitting device, a wafer, and a method for manufacturing the semiconductor light emitting device can be provided.

In the specification, “nitride semiconductor” includes all compositions of semiconductors of the chemical formula BₓIn_{y}Al_{z}Ga_{1-x-y-z}N (0≦x≦1, 0≦z≦1, and x+y+z≦1) for which the compositional proportions x, y, and z are changed within the ranges respectively. “Nitride semiconductor” further includes group V elements other than N (nitrogen) in the chemical formula recited above, various elements added to control various properties such as the conductivity type and the like, and various elements included unintentionally.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the invention is not limited to these specific examples. For example, one skilled in the art may similarly practice the invention by appropriately selecting specific configurations of components included in semiconductor light emitting devices such as first semiconductor layers, active layers, second semiconductor layers, support substrates, electrodes, and insulating layers, components included in wafers such as substrates, oxide crystal films, oxide layers, semiconductor crystal films, and the like from known art; and such practice is included in the scope of the invention to the extent that similar effects are obtained.

Further, any two or more components of the specific examples may be combined within the extent of technical feasibility and are included in the scope of the invention to the extent that the purport of the invention is included.

Moreover, all semiconductor light emitting devices, wafers, and methods for manufacturing semiconductor light emitting devices practicable by an appropriate design modification by one skilled in the art based on the semiconductor light emitting devices, the wafers, and the methods for manufacturing semiconductor light emitting devices described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor light emitting device, comprising:
a first semiconductor layer of a first conductivity type having a first upper surface and a first side surface and including a nitride semiconductor;
an active layer having a first portion and a second portion, the first portion covering at least a portion of the first upper surface and having a second upper surface stacked with the first upper surface along a stacking direction, the second portion covering at least a portion of the first side surface and having a second side surface stacked with the first side surface along a first direction; and
a second semiconductor layer of a second conductivity type having a third portion and a fourth portion, the third portion covering at least a portion of the second upper surface, the fourth portion covering at least a portion of the second side surface, the second conductivity type being different from the first conductivity type, the second semiconductor layer including a nitride semiconductor,
a thickness of the first portion along the stacking direction being thicker than a thickness of the second portion along the first direction,
a thickness of the third portion along the stacking direction being thicker than a thickness of the fourth portion along the first direction.

2. The device according to claim 1, wherein a distance from a center of the first portion along the first direction to a center of the second portion along the first direction is not more than 50 micrometers.

3. The device according to claim 1, wherein an intensity of light emitted from the second portion is lower than an intensity of light emitted from the first portion.

4. The device according to claim 1, wherein a third upper surface of the third portion and the second upper surface are a c-plane.

5. The device according to claim 1, wherein a third side surface of the fourth portion and the second side surface are perpendicular to a c-plane.

6. The device according to claim 1, wherein
the first semiconductor layer includes at least one of GaN, InGaN and AlGaN, and
the second semiconductor layer includes at least one of GaN, InGaN and AlGaN.

7. A wafer, comprising:
a substrate of a semiconductor, the substrate having a major surface;
an oxide crystal film provided on the major surface;
an oxide layer provided on a portion of the oxide crystal film, the oxide layer having a first pattern portion; and
a semiconductor crystal film provided on a first region and a second region of the oxide crystal film, the first region and the second region being disposed on two sides of the first pattern portion, the semiconductor crystal film having a crystal orientation reflecting a crystal orientation of the substrate, the semiconductor crystal film including a nitride semiconductor,
the semiconductor crystal film having a gap provided on the first pattern portion between at least a portion of the semiconductor crystal film grown from the first region and at least a portion of the semiconductor crystal film grown from the second region.

8. The wafer according to claim 7, wherein a distance from a center of the first portion along the first direction to a center of the second portion along the first direction is not more than 50 micrometers.

9. The wafer according to claim 7, wherein a third upper surface of the third portion and the second upper surface are a c-plane.

10. The wafer according to claim 7, wherein a third side surface of the fourth portion and the second side surface are perpendicular to a c-plane.

11. A method for manufacturing a semiconductor light emitting device, comprising:
forming a first oxide crystal film on a major surface of a substrate of a semiconductor;
forming a first oxide layer on a portion of the first oxide crystal film, the first oxide layer having a first pattern portion; and
growing a first semiconductor crystal film on a first region and a second region of the first oxide crystal film, the first region and the second region being disposed on two sides of the first pattern portion, the first semiconductor crystal film having a crystal orientation reflecting a crystal orientation of the substrate, the first semiconductor crystal film including a nitride semiconductor,
the growing of the first semiconductor crystal film including making a gap on the first pattern portion between at least a portion of the first semiconductor crystal film grown from the first region and at least a portion of the first semiconductor crystal film grown from the second region.

12. The method according to claim 11, wherein:
the first oxide layer has a second pattern portion distal to the first pattern portion;
the first region is disposed between the first pattern portion and the second pattern portion;
the first oxide crystal film further includes a third region, and the second pattern portion is disposed between the first region and the third region;
the growing of the first semiconductor crystal film includes growing the first semiconductor crystal film on the third region;
the growing of the first semiconductor crystal film includes making a gap on the second pattern portion between at least a portion of the first semiconductor crystal film grown from the first region and at least a portion of the first semiconductor crystal film grown from the third region; and
a width between the first pattern portion and the second pattern portion along a first direction from the first pattern portion toward the second pattern portion being wider than a width of the first pattern portion along the first direction and wider than a width of the second pattern portion along the first direction.

13. The method according to claim 12, wherein a configuration of the first region, the second region and the third region as viewed from a direction perpendicular to the major surface is a polygon having an angle of 60 degrees or 120 degrees.

14. The method according to claim 12, wherein the width of the first pattern portion along the first direction is not more than 15 micrometers and the width of the second pattern portion along the first direction is not more than 15 micrometers.

15. The method according to claim 11, wherein a configuration of the first region as viewed from a direction perpendicular to the major surface is a polygon having an angle of 60 degrees or 120 degrees.

16. The method according to claim 11, further comprising separating the substrate from the first semiconductor crystal film by removing the first oxide crystal film and the first oxide layer by wet processing via the gap after the growing of the first semiconductor crystal film.

17. The method according to claim 11, further comprising:
forming a second oxide crystal film on the major surface of the substrate separated from the first semiconductor crystal film;
forming a second oxide layer on a portion of the second oxide crystal film, the second oxide layer having a third pattern portion; and
growing a second semiconductor crystal film on a fourth region and a fifth region of the second oxide crystal film, the fourth region and the fifth region being disposed on two sides of the second oxide layer, the second semiconductor crystal film having a crystal orientation reflecting a crystal orientation of the substrate, the second semiconductor crystal film including a nitride semiconductor,
the growing of the second semiconductor crystal film including making a gap on the third pattern portion between at least a portion of the second semiconductor crystal film grown from the fourth region and at least a portion of the second semiconductor crystal film grown from the fifth region.

18. The method according to claim 11, wherein a thickness of the first oxide crystal film is not less than 0.5 nanometers and not more than 20 nanometers.

19. The method according to claim 11, wherein the first oxide crystal film includes an oxide of at least one of Zn and Mg.

20. The method according to claim 11, wherein the first oxide layer includes an oxide of Si.
